(19) United States
(12) Patent Application Publication
(10) Pub. No.: US 2026/0239575 A1
(43) Pub. Date: Aug. 13, 2026

(54) SYSTEMS AND METHODS FOR CONFIGURING AN INFORMATION HANDLING SYSTEM USING CONSTRAINTS AS INPUTS

(71) Applicant: Dell Products L.P., Round Rock, TX (US)

(72) Inventors: Sudhir Vittal Shetty, Cedar Park, TX (US); Rhushabh Bhandari, Pflugerville, TX (US); Nadia Henry, Georgetown, TX (US); Carlos Guillermo Henry, Georgetown, TX (US); Kwangnam Cho, Round Rock, TX (US); Deepak Gowda, Raleigh, NC (US)

(73) Assignee: Dell Products L.P., Round Rock, TX (US)

(21) Appl. No.: 19/047,741

(22) Filed: Feb. 7, 2025

(51) Int. Cl. H05K 7/20; G06F 1/18

(52) U.S. Cl. CPC H05K 7/207; G06F 1/189

(57) ABSTRACT

Systems and methods are provided for configuring an information handling system (IHS) for deployment in a data center. A method may include receiving input from a user, where that input indicates a data center-level constraint for the IHS. The method may further include applying the input to a machine learning (ML) algorithm to provide output. The output from the ML algorithm may identify a hardware configuration for the IHS, where that hardware configuration conforms to the constraint.

### FIELD

The present disclosure generally relates to Information Handling Systems (IHSs), and, more particularly, to configuring IHSs using constraints as inputs.

### BACKGROUND

As the value and use of information continues to increase, individuals and businesses seek additional ways to process and store information. One option available to users is Information Handling Systems (IHSs). An IHS generally processes, compiles, stores, and/or communicates information or data for business, personal, or other purposes thereby allowing users to take advantage of the value of the information. Because technology and information handling needs and requirements vary between different users or applications, IHSs may also vary regarding what information is handled, how the information is handled, how much information is processed, stored, or communicated, and how quickly and efficiently the information may be processed, stored, or communicated. The variations in IHSs allow for IHSs to be general or configured for a specific user or specific use such as financial transaction processing, airline reservations, enterprise data storage, or global communications. In addition, IHSs may include a variety of hardware and software components that may be configured to process, store, and communicate information and may include one or more computer systems, data storage systems, and networking systems.

Groups of IHSs may be housed within data center environments. A datacenter may include a large number of IHSs, such as servers, that are installed within chassis and stacked within slots provided by racks. A datacenter may include large numbers of such racks that are filled with servers, or other types of IHSs.

### SUMMARY

In various embodiments, an information handling system (IHS) includes: a plurality of managed hardware components; one or more processors; and one or more memory devices coupled to the one or more processors, the memory devices storing computer-readable instructions that, upon execution by the one or more processors, cause the IHS to: receive input indicating a data center-level constraint for a data center computer; apply the input to a trained machine learning (ML) model to cause the ML model to generate configuration data for the data center computer, wherein the configuration data specifies a hardware implementation of the data center computer having characteristics conforming to the data center-level constraint; and provide the configuration data for the data center computer to a user via a user interface.

In various embodiments, a method includes: receiving input indicating an information handling system (IHS) size and a data center-level thermal constraint; applying the input to a trained machine learning (ML) model to cause the ML model to generate configuration data for an IHS, wherein the configuration data specifies a hardware implementation of the data center computer having characteristics conforming to the IHS size and the data center-level thermal constraint; and providing the configuration data for the data center computer to a user via a user interface.

In various embodiments, a computer-readable storage device having instructions stored thereon for configuring a data center computer, wherein execution of the instructions by one or more processors of an information handling system (IHS) causes the one or more processors to: receiving input indicating a data center mandate for a thermal characteristic of the data center computer and a power characteristic of the data center computer; applying the input to a trained ML model to cause the trained ML model to generate a predicted hardware configuration for the data center computer, wherein the hardware configuration comprises a component-level specification for the data center computer; and outputting the predicted hardware configuration to a user with an option to cause the data center computer to be built according to the hardware configuration.

### BRIEF DESCRIPTION OF THE DRAWINGS

The present invention(s) is/are illustrated by way of example and is/are not limited by the accompanying figures. Elements in the figures are illustrated for simplicity and clarity and have not necessarily been drawn to scale.

FIG. 1 is a diagram illustrating certain components of a chassis, according to some embodiments.

FIG. 2 is a diagram illustrating certain components of an IHS configured as a component of chassis, according to some embodiments.

FIG. 3 is an illustration of an example data center, according to some embodiments.

FIG. 4 is an illustration of an example system, for configuring an IHS, according to some embodiments.

FIG. 5 is an illustration of an example method, for configuring a data center computer, according to some embodiments.

### DETAILED DESCRIPTION

Various embodiments are directed to a configuration application, which is operable to allow a user to enter input indicating constraints, apply those constraints to a machine learning (ML) model during a prediction phase of the ML model, and receive as output from the ML model data indicating a hardware implementation of an IHS. The hardware implementation of the IHS may conform to the constraints. The configuration application may display the data indicating the hardware implementation to the user on a user interface. Furthermore, the user may request that the IHS be manufactured, and an entity associated with the configuration application may then build and deliver the IHS to the user.

In one example, the configuration application may be trained to output the hardware configuration from among a plurality of pre-defined configurations. In another example, the configuration application may be trained to output an entirely new configuration that has not been pre-defined. In yet another example, the configuration application may be trained to provide the data indicating the hardware configuration as an update to an existing hardware configuration to meet the constraints.

In one example use case, the constraints may be data center-level constraints, such as may relate to power use or airflow, where power use is expected to be provided by a shared power resource of the data center, and where airflow depends on a shared cooling resource of the data center.

Further in the example use case, the input from the user may specify no particular hardware configuration or hardware component. For instance, the user may simply input constraints and receive as output the data indicating the hardware implementation. This use case example is different from current configuration applications that may receive input identifying hardware components and allow a user to build a rack-based server system by adding the hardware components to a proposed design.

A potential advantage of some embodiments is that it may allow users to build IHSs that comply with constraints rather than force a user to build a hardware implementation in the application and then determine whether the resulting performance characteristics comply with data center-level constraints. More specifically, a user may desire to specify a hardware implementation of an IHS to be built and delivered, and the user may plan to deploy the IHS in a data center, where the data center may mandate certain constraints (e.g., data center-level constraints). Various implementations herein may allow the user to enter the constraints as input, without having to enter certain hardware components, and to receive the data indicating the hardware implementation as output.

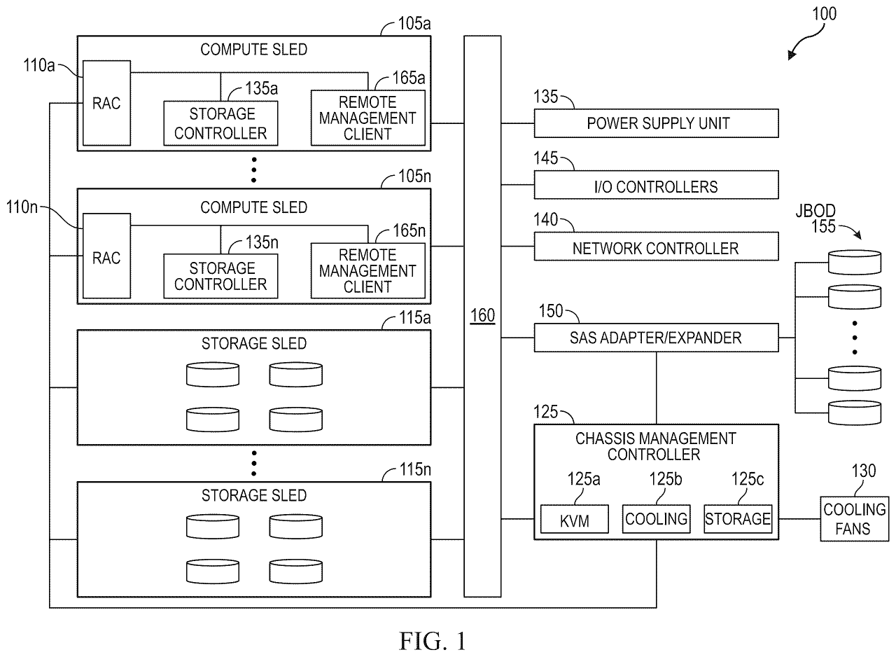

FIG. 1 is a block diagram illustrating certain components of a chassis 100 comprising one or more compute sleds 105a-n and one or more storage sleds 115a-n, where each of the sleds 105a-n, 115a-n may be configured by a configuration application. Chassis 100 may include one or more bays that each receive an individual sled (that may be additionally or alternatively referred to as a tray, blade, and/or node), such as compute sleds 105a-n and storage sleds 115a-n. Chassis 100 may support a variety of different numbers (e.g., 4, 8, 16, 32), sizes (e.g., single-width, double-width) and physical configurations of bays. Other embodiments may include additional types of sleds that provide various types of storage and/or processing capabilities. Other types of sleds may provide power management and networking functions. Sleds may be individually installed and removed from the chassis 100, thus allowing the computing and storage capabilities of a chassis to be reconfigured by swapping the sleds with different types of sleds, in many cases without affecting the operations of the other sleds installed in the chassis 100.

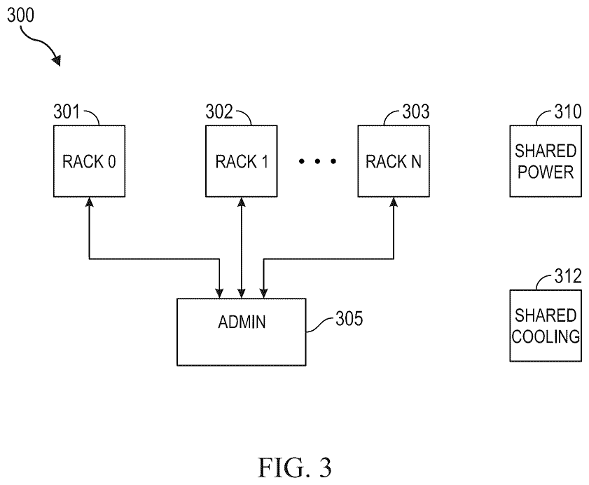

Multiple chassis 100 may be housed within a rack, such as any of the racks illustrated in FIG. 3. Data centers may utilize large numbers of racks, with various different types of chassis installed in the various configurations of racks. The modular architecture provided by the sleds, chassis and rack allow for certain resources, such as cooling, power and network bandwidth, to be shared by the compute sleds 105a-n and storage sleds 115a-n, thus providing efficiency improvements and supporting greater computational loads.

Chassis 100 may be installed within a rack structure that provides all or part of the cooling utilized by chassis 100. For airflow cooling, a rack may include one or more banks of cooling fans that may be operated to ventilate heated air from within the chassis 100 that is housed within the rack. The chassis 100 may alternatively or additionally include one or more cooling fans 130 that may be similarly operated to ventilate heated air from within the sleds 105a-n, 115a-n installed within the chassis. A rack and a chassis 100 installed within the rack may utilize various configurations and combinations of cooling fans to cool the sleds 105a-n, 115a-n and other components housed within chassis 100.

The sleds 105a-n, 115a-n may be individually coupled to chassis 100 via connectors that correspond to the bays provided by the chassis 100 and that physically and electrically couple an individual sled to a backplane 160. Chassis backplane 160 may be a printed circuit board that includes electrical traces and connectors that are configured to route signals between the various components of chassis 100 that are connected to the backplane 160. In various embodiments, backplane 160 may include various additional components, such as cables, wires, midplanes, backplanes, connectors, expansion slots, and multiplexers. In certain embodiments, backplane 160 may be a motherboard that includes various electronic components installed thereon. Such components installed on a motherboard backplane 160 may include components that implement all or part of the functions described with regard to the SAS (Serial Attached SCSI) expander 150, I/O controllers 145, network controller 145 and power supply unit 135.

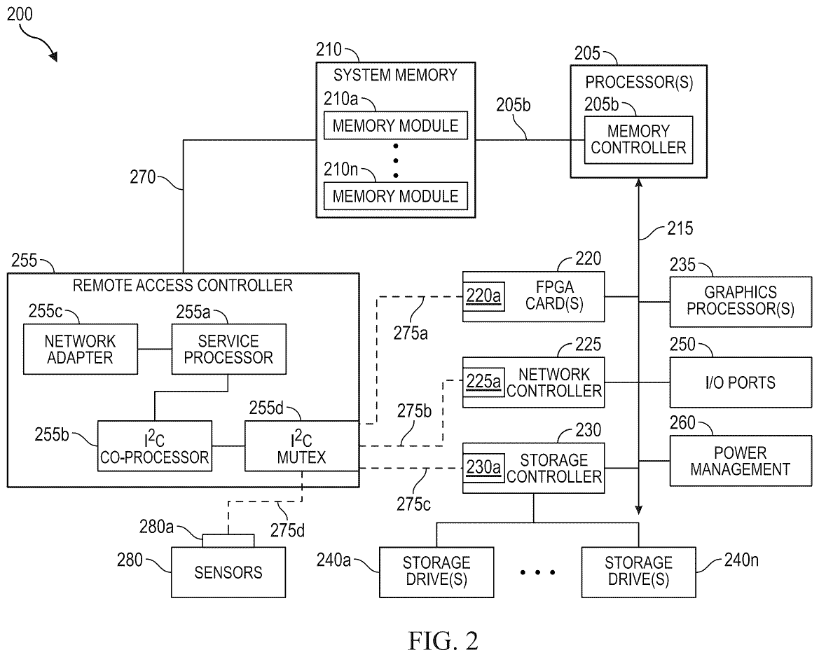

In certain embodiments, a compute sled 105a-n may be an IHS such as described with regard to IHS 200 of FIG. 2. A compute sled 105a-n may provide computational processing resources that may be used to support a variety of e-commerce, multimedia, business and scientific computing applications, such as services provided via a cloud implementation. Compute sleds 105a-n may be configured with hardware and software that provide leading-edge computational capabilities. Accordingly, services provided using such computing capabilities may be provided as high-availability systems that operate with minimum downtime. As described in additional detail with regard to FIG. 2, compute sleds 105a-n may be configured for general-purpose computing or may be optimized for specific computing tasks.

As illustrated, each compute sled 105a-n includes a remote access controller (RAC) 110a-n. As described in additional detail with regard to FIG. 2, remote access controller 110a-n provides capabilities for remote monitoring and management of compute sled 105a-n. In support of these monitoring and management functions, remote access controllers 110a-n may utilize both in-band and sideband (i.e., out-of-band) communications with various components of a compute sled 105a-n and chassis 100. Remote access controllers 110a-n may collect sensor data, such as temperature sensor readings, from components of the chassis 100 in support of airflow cooling of the chassis 100 and the sleds 105a-n, 115a-n. Remote access controllers 110a-n may collect data, such as for power use, memory use, compute power use, clocking, sled configuration, and the like, for their respective sleds.

In addition, each remote access controller 110a-n may implement various monitoring and administrative functions related to compute sleds 105a-n that employ sideband bus connections with various internal components of the respective compute sleds 105a-n. As described in additional detail below, remote access controllers 110a-n also support remote monitoring and management of various internal components of the respective compute sleds 105a-n via in-band communications that are supported by the operating systems of the respective compute sleds 105a-n. In

As illustrated, chassis 100 also includes one or more storage sleds 115a-n that are coupled to the backplane 160 and installed within one or more bays of chassis 200 in a similar manner to compute sleds 105a-n. Each of the individual storage sleds 115a-n may include various different numbers and types of storage devices. For instance, storage sleds 115a-n may include SAS (Serial Attached SCSI) magnetic disk drives, SATA (Serial Advanced Technology Attachment) magnetic disk drives, solid-state drives (SSDs) and other types of storage drives in various combinations. The storage sleds 115a-n may be utilized in various storage configurations by the compute sleds 105a-n that are coupled to chassis 100.

Each of the compute sleds 105a-n includes a storage controller 135a-n that may be utilized to access storage drives that are accessible via chassis 100. Some of the individual storage controllers 135a-n may provide support for RAID (Redundant Array of Independent Disks) configurations of logical and physical storage drives, such as storage drives provided by storage sleds 115a-n. In some embodiments, some or all of the individual storage controllers 135a-n may be HBAs (Host Bus Adapters) that provide more limited capabilities in accessing physical storage drives provided via storage sleds 115a-n and/or via SAS expander 150.

In addition to the data storage capabilities provided by storage sleds 115a-n, chassis 100 may provide access to other storage resources that may be installed components of chassis 100 and/or may be installed elsewhere within a rack housing the chassis 100, such as within a storage blade. In certain scenarios, such storage resources 155 may be accessed via a SAS expander 150 that is coupled to the backplane 160 of the chassis 100. The SAS expander 150 may support connections to a number of JBOD (Just a Bunch Of Disks) storage drives 155 that may be configured and managed individually and without implementing data redundancy across the various drives 155. The additional storage resources 155 may also be at various other locations within a datacenter in which chassis 100 is installed. Such additional storage resources 155 may also be remotely located.

As illustrated, the chassis 100 of FIG. 1 includes a network controller 140 that provides network access to the sleds 105a-n, 115a-n installed within the chassis. Network controller 140 may include various switches, adapters, controllers and couplings used to connect chassis 100 to a network, either directly or via additional networking components and connections provided via a rack in which chassis 100 is installed. Chassis 100 may similarly include a power supply unit 135 that provides the components of the chassis with various levels of DC power from an AC power source or from power delivered via a power system provided by a rack within which chassis 100 may be installed. In certain embodiments, power supply unit 135 may be implemented within a sled that may provide chassis 100 with redundant, hot-swappable power supply units.

Chassis 100 may also include various I/O controllers 140 that may support various I/O ports, such as USB ports that may be used to support keyboard and mouse inputs and/or video display capabilities. Such I/O controllers 145 may be utilized by the chassis management controller 125 to support various KVM (Keyboard, Video and Mouse) 125a capabilities that provide administrators with the ability to interface with the chassis 100. The chassis management controller 125 may also include a storage module 125c that provides capabilities for managing and configuring certain aspects of the storage devices of chassis 100, such as the storage devices provided within storage sleds 115a-n and within the JBOD 155.

In addition to providing support for KVM 125a capabilities for administering chassis 100, chassis management controller 125 may support various additional functions for sharing the infrastructure resources of chassis 100. In some scenarios, chassis management controller 125 may implement tools for managing the power 135, network bandwidth 140 and airflow cooling 130 that are available via the chassis 100. The airflow cooling 130 utilized by chassis 100 may include an airflow cooling system that is provided by a rack in which the chassis 100 may be installed and managed by a cooling module 125b of the chassis management controller 125.

For purposes of this disclosure, an IHS may include any instrumentality or aggregate of instrumentalities operable to compute, calculate, determine, classify, process, transmit, receive, retrieve, originate, switch, store, display, communicate, manifest, detect, record, reproduce, handle, or utilize any form of information, intelligence, or data for business, scientific, control, or other purposes. For example, an IHS may be a personal computer (e.g., desktop or laptop), tablet computer, mobile device (e.g., Personal Digital Assistant (PDA) or smart phone), server (e.g., blade server or rack server), a compute sled, a storage sled, a network storage device, or any other suitable device and may vary in size, shape, performance, functionality, and price. An IHS may include Random Access Memory (RAM), one or more processing resources such as a Central Processing Unit (CPU) or hardware or software control logic, Read-Only Memory (ROM), and/or other types of nonvolatile memory. Additional components of an IHS may include one or more disk drives, one or more network ports for communicating with external devices as well as various I/O devices, such as a keyboard, a mouse, touchscreen, and/or a video display. As described, an IHS may also include one or more buses operable to transmit communications between the various hardware components. An example of an IHS is described in more detail below.

FIG. 2 shows an example of an IHS 200 that may be configured using a configuration application. It should be appreciated that although the embodiments described herein may describe an IHS that is a compute sled or similar computing component that may be deployed within the bays of a chassis, other embodiments may be utilized with other types of IHSs. In the illustrative embodiment of FIG. 2, IHS 200 may be a computing component, such as compute sled 105a-n or other type of server, such as a 1RU server installed within a 2RU chassis, that is configured to share infrastructure resources provided by a chassis 100.

The IHS 200 of FIG. 2 may be a compute sled, such as compute sleds 105a-n of FIG. 1, that may be installed within a chassis, that may in turn be installed within a rack. Installed in this manner, IHS 200 may utilize shared power, network and cooling resources provided by the chassis and/or rack. IHS 200 may utilize one or more processors 205. In some embodiments, processors 205 may include a main processor and a co-processor, each of which may include a plurality of processing cores that, in certain scenarios, may each be used to run an instance of a server process. In certain embodiments, one or all of processor(s) 205 may be graphics processing units (GPUs) in scenarios where IHS 200 has been configured to support functions such as multimedia services and graphics applications.

As illustrated, processor(s) 205 includes an integrated memory controller 205a that may be implemented directly within the circuitry of the processor 205, or the memory controller 205a may be a separate integrated circuit that is located on the same die as the processor 205. The memory controller 205a may be configured to manage the transfer of data to and from the system memory 210 of the IHS 205 via a high-speed memory interface 205b.

The system memory 210 is coupled to processor(s) 205 via a memory bus 205b that provides the processor(s) 205 with high-speed memory used in the execution of computer program instructions by the processor(s) 205. Accordingly, system memory 210 may include memory components, such as such as static RAM (SRAM), dynamic RAM (DRAM), NAND Flash memory, suitable for supporting high-speed memory operations by the processor(s) 205. In certain embodiments, system memory 210 may combine both persistent, non-volatile memory and volatile memory.

In certain embodiments, the system memory 210 may include multiple removable memory modules. The system memory 210 of the illustrated embodiment includes removable memory modules 210a-n. Each of the removable memory modules 210a-n may correspond to a printed circuit board memory socket that receives a removable memory module 210a-n, such as a DIMM (Dual In-line Memory Module), that can be coupled to the socket and then decoupled from the socket as needed, such as to upgrade memory capabilities or to replace faulty components. Other embodiments of IHS system memory 210 may be configured with memory socket interfaces that correspond to different types of removable memory module form factors, such as a Dual In-line Package (DIP) memory, a Single In-line Pin Package (SIPP) memory, a Single In-line Memory Module (SIMM), and/or a Ball Grid Array (BGA) memory.

IHS 200 may utilize a chipset that may be implemented by integrated circuits that are connected to each processor 205. All or portions of the chipset may be implemented directly within the integrated circuitry of an individual processor 205. The chipset may provide the processor(s) 205 with access to a variety of resources accessible via one or more in-band buses 215. Various embodiments may utilize any number of buses to provide the illustrated pathways served by in-band bus 215. In certain embodiments, in-band bus 215 may include a PCIe (PCI Express) switch fabric that is accessed via a PCIe root complex. IHS 200 may also include one or more I/O ports 250, such as PCIe ports, that may be used to couple the IHS 200 directly to other IHSs, storage resources or other peripheral components.

As illustrated, IHS 200 may include one or more FPGA (Field-Programmable Gate Array) card(s) 220. Each of the FPGA card 220 supported by IHS 200 may include various processing and memory resources, in addition to an FPGA logic unit that may include circuits that can be reconfigured after deployment of IHS 200 through programming functions supported by the FPGA card 220. Through such reprogramming of the logic units, each individual FGPA card 220 may be optimized to perform specific processing tasks, such as specific signal processing, security, data mining, and artificial intelligence functions, and/or to support specific hardware coupled to IHS 200. In some embodiments, a single FPGA card 220 may include multiple FPGA logic units, each of which may be separately programmed to implement different computing operations, such as in computing different operations that are being offloaded from processor 205. The FPGA card 220 may also include a management controller 220a that may support interoperation with the remote access controller 255 via a sideband device management bus 275a.

Processor(s) 205 may also be coupled to a network controller 225 via in-band bus 215, such as provided by a Network Interface Controller (NIC) that allows the IHS 200 to communicate via an external network, such as the Internet or a LAN. In some embodiments, network controller 225 may be a replaceable expansion card or adapter that is coupled to a motherboard connector of IHS 200. In some embodiments, network controller 225 may be an integrated component of IHS 200.

A variety of additional components may be coupled to processor(s) 205 via in-band bus 215. For instance, processor(s) 205 may also be coupled to a power management unit 260 that may interface with the power system unit 135 of the chassis 100 in which an IHS, such as a compute sled, may be installed. In certain embodiments, a graphics processor 235 may be comprised within one or more video or graphics cards, or an embedded controller, installed as components of the IHS 200. In certain embodiments, graphics processor 235 may be an integrated component of the remote access controller 255 and may be utilized to support the display of diagnostic and administrative interfaces related to IHS 200 via display devices that are coupled, either directly or remotely, to remote access controller 255.

In certain embodiments, IHS 200 may operate using a BIOS (Basic Input/Output System) that may be stored in a non-volatile memory accessible by the processor(s) 205. The BIOS may provide an abstraction layer by which the operating system of the IHS 200 interfaces with the hardware components of the IHS. Upon powering or restarting IHS 200, processor(s) 205 may utilize BIOS instructions to initialize and test hardware components coupled to the IHS, including both components permanently installed as components of the motherboard of IHS 200 and removable components installed within various expansion slots supported by the IHS 200. The BIOS instructions may also load an operating system for use by the IHS 200. In certain embodiments, IHS 200 may utilize Unified Extensible Firmware Interface (UEFI) in addition to or instead of a BIOS. In certain embodiments, the functions provided by a BIOS may be implemented, in full or in part, by the remote access controller 255.

In certain embodiments, remote access controller 255 may operate from a different power plane from the processors 205 and other components of IHS 200, thus allowing the remote access controller 255 to operate, and management tasks to proceed, while the processing cores of IHS 200 are powered off. As described, various functions provided by the BIOS, including launching the operating system of the IHS 200, may be implemented by the remote access controller 255. In some embodiments, the remote access controller 255 may perform various functions to verify the integrity of the IHS 200 and its hardware components prior to initialization of the IHS 200 (i.e., in a bare-metal state).

Remote access controller 255 may include a service processor 255a, or specialized microcontroller, that operates management software that supports remote monitoring and administration of IHS 200. Remote access controller 255 may be installed on the motherboard of IHS 200 or may be coupled to IHS 200 via an expansion slot provided by the motherboard. In support of remote monitoring functions, network adapter 225c may support connections with remote access controller 255 using wired and/or wireless network connections via a variety of network technologies. As a non-limiting example of a remote access controller, the integrated Dell Remote Access Controller (iDRAC) from Dell® is embedded within Dell PowerEdge™ servers and provides functionality that helps information technology (IT) administrators deploy, update, monitor, and maintain servers remotely.

In some embodiments, remote access controller 255 may support monitoring and administration of various managed devices 220, 225, 230, 280 of an IHS via a sideband bus interface. For instance, messages utilized in device management may be transmitted using I2C sideband bus connections 275a-d that may be individually established with each of the respective managed devices 220, 225, 230, 280 through the operation of an I2C multiplexer 255d of the remote access controller. As illustrated, certain of the managed devices of IHS 200, such as FPGA cards 220, network controller 225 and storage controller 230, are coupled to the IHS processor(s) 205 via an in-line bus 215, such as a PCIe root complex, that is separate from the I2C sideband bus connections 275a-d used for device management. In various embodiments, additional or different components of IHS 200 may be managed by remote access controller 225 through the use of sideband bus connections. The management functions of the remote access controller 255 may utilize information collected by various managed sensors 280 located within the IHS. For instance, temperature data collected by sensors 280 may be utilized by the remote access controller 255 in support of closed-loop airflow cooling of the IHS 200.

In certain embodiments, the service processor 255a of remote access controller 255 may rely on an I2C co-processor 255b to implement sideband I2C communications between the remote access controller 255 and managed components 220, 225, 230, 280 of the IHS. The I2C co-processor 255b may be a specialized co-processor or micro-controller that is configured to interface via a sideband I2C bus interface with the managed hardware components 220, 225, 230, 280 of IHS. In some embodiments, the I2C co-processor 255b may be an integrated component of the service processor 255a, such as a peripheral system-on-chip feature that may be provided by the service processor 255a. Each I2C bus 275a-d is illustrated as single line in FIG. 2. However, each I2C bus 275a-d may be comprised of a clock line and data line that couple the remote access controller 255 to I2C endpoints 220a, 225a, 230a, 280a which may be referred to as modular field replaceable units (FRUs).

As illustrated, the I2C co-processor 255b may interface with the individual managed devices 220, 225, 230, 280 via individual sideband I2C buses 275a-d selected through the operation of an I2C multiplexer 255d. Via switching operations by the I2C multiplexer 255d, a sideband bus connection 275a-d may be established by a direct coupling between the I2C co-processor 255b and an individual managed device 220, 225, 230, 280.

In providing sideband management capabilities, the I2C co-processor 255b may each interoperate with corresponding endpoint I2C controllers 220a, 225a, 230a, 280a that implement the I2C communications of the respective managed devices 220, 225, 230. The endpoint I2C controllers 220a, 225a, 230a, 280a may be implemented as a dedicated microcontroller for communicating sideband I2C messages with the remote access controller 255, or endpoint I2C controllers 220a, 225a, 230a, 280a may be integrated SoC functions of a processor of the respective managed device endpoints 220, 225, 230, 280. In certain embodiments, the endpoint I2C controller 280a of the FPGA card 220 may correspond to the management controller 220a described above.

In various embodiments, an IHS 200 does not include each of the components shown in FIG. 2. In various embodiments, an IHS 200 may include various additional components in addition to those that are shown in FIG. 2. Furthermore, some components that are represented as separate components in FIG. 2 may in certain embodiments instead be integrated with other components. For example, in certain embodiments, all or a portion of the functionality provided by the illustrated components may instead be provided by components integrated into the one or more processor(s) 205 as a systems-on-a-chip.

FIG. 3 is an illustration of an example data center 300, according to some embodiments. Data center 300 includes N racks 301-303, where N is a positive integer greater than one, though this particular illustration shows three racks 301-303. However, the scope of implementations may include any appropriate quantity N of racks.

Each of the racks 301-303 may include one or more chassis, where an example chassis 100 is described above with respect to FIG. 1. Each chassis in a rack may include one or multiple IHSs, such as one or multiple compute sleds, storage sleds, and/or the like. In some examples, an IHS in a rack may be referred to as a server, though the scope of implementations is not limited to servers.

Admin computing rack 305 may include one or multiple chassis having one or multiple IHSs that run applications for administration of the data center. Shared power resource 310 may include power converters, buses, and the like, to provide power to the racks 301-303, the admin rack 305, shared cooling resource 312, and any other components of the data center 300. For instance, shared power resource 310 may receive electricity from a power line (not shown) or substation (not shown), which is external to the data center 300 and then distribute that power to the various components within the data center.

Shared cooling resource 312 may include various data center-level cooling technologies, which support heat removal from racks 301-303, admin rack 305, shared power resource 310, and any other appropriate components of data center 300. In one example, shared cooling resource 312 may include a central air conditioning system, which operates to keep the data center 300 within a specified temperature range (e.g., 15°C.-32°C.). Shared cooling resource 312 may include other technologies, such as central fluid cooling, where fluid from one or more of the racks 301-303 may circulate through shared cooling resource 312 for heat to be removed and the fluid to be recirculated.

As noted above, shared power resource 310 may power the various components of the data center 300, including the shared cooling resource 312. Thus, power usage within the data center 300 may include not only components directly related to powering computing and storage resources (e.g., racks 301-303 and admin rack 305) but may also include power usage related to shared cooling resource 312. Thus, as power use increases for racks 301-303, that may be expected to increase heat released into the atmosphere of the data center 300, which may place increased burden on the shared cooling resource 312, and the shared cooling resource 312 may in response also consume more power.

Shared power resource 300 and shared cooling resource 312 represent data center-level resources. In other words, shared power resource 300 and shared cooling resource 312 are not specific to any particular rack, but rather, serve all N of the racks 301-303.

Admin rack 305 may include an IHS (not shown), which communicates with individual ones of the IHSs of the racks 301-303. For instance, in one example, the various IHSs within rack 301 may communicate with an IHS of admin 305 over a network, such as ethernet or a wireless network such as Wi-Fi. Example, each of the IHSs may include a remote access controller, which in some implementations may also be referred to as a baseboard management controller (BMC). The remote access controller for a given IHS may monitor configuration of the IHS, monitor performance characteristics of the IHS, and control some operations of various components of the IHS. Furthermore, a given IHS may transmit remote access controller data to an IHS of the admin rack 305, and the IHS of the admin rack 305 may communicate to an IHS of a given rack to cause action on the part of the remote access controller.

The design of the data center 300 may be associated with constraints that may be placed on the IHSs of the racks 301-303. For instance, operation of an IHS may affect the power consumed from the shared power resource 310 and may also affect use of the shared cooling resource 312, as explained above. Additionally, data center 300 may have further operational design characteristics that lead to constraints for, e.g., acoustic output of the IHSs in the racks 301-303. As a result, when data center 300 is being designed, engineers may place constraints upon the IHSs to be deployed within the data center 300, such as by mandating certain characteristics.

One example constraint may include ambient support. An example ambient support may indicate an ambient temperature of the data center. For instance, the shared cooling resource 312 may provide air conditioning and airflow to maintain a specific ambient temperature (e.g., 15°C.-32°C).

Another example constraint may include server height. Server height may be specified in rack units, sometimes abbreviated as U. For instance, the data center 300 may include a particular ceiling height and may have other infrastructure deployed between the ceiling and the floor, and such characteristics may lead to a preferred or mandated maximum and/or minimum server height, specified in rack units U.

Air temperature rise is another example constraint that may be dictated at the data center-level. Air temperature rise refers to an increase in temperature of air as it passes through a rack, chassis, or standalone IHS. For instance, if the ambient temperature of the data center is 25° C., and the air temperature rise of an IHS is 30° C., then the exhaust air temperature from the IHS is 55° C. A data center may indicate a maximum allowable increase in temperature relative to the ambient temperature of the air of the data center 300. Limiting air temperature rise may assist the designer of the data center 300 in designing the shared cooling resource 312 to handle the heat generated by a rack, chassis, or IHS. When expressed as a constraint, air temperature rise may be a not-to-exceed value.

Airflow is another example constraint. Airflow refers to the volume of air used to cool a rack, chassis, and/or IHS. Airflow may be measured, e.g., in cubic feet per minute. The amount of airflow and air temperature rise may affect the operation of the shared cooling resource 312. Furthermore, efficient airflow management may be used to prevent hotspots and ensure even cooling throughout the data center. When expressed as a constraint, airflow may be a target average over time.

Acoustic constraints are another type of constraint that may be dictated by the data center. Acoustic output of a rack, chassis, and/or IHS may be measured, e.g., in decibels. In some data centers, acoustic output may be considered disruptive, and a design of the data center may mandate a maximum level of acoustic output. When expressed as a constraint, acoustic output may be a not-to-exceed value in decibels. In another example, power consumption of an IHS may be used as a proxy for acoustic noise, and the acoustic constraint may be expressed as a power consumption limit, e.g., in watts.

Power and cooling per rack is another example constraint. It refers to total power consumption and cooling capacity for a rack as a whole. For instance, high-density racks may consume more power and generate more heat than less dense racks. Some data centers may mandate rack power and rack cooling characteristics to achieve power distribution and cooling strategies to prevent overheating. Power per rack, when expressed as a constraint, may include a not-to-exceed value for power consumption or a target average. Cooling per rack, when expressed as a constraint, may indicate a minimum cooling capacity per rack or a target cooling capacity per rack.

Power consumption is another example constraint, and it may refer to IHS-level power consumption, such as measured in watts. Power consumption may be constrained by the ability of shared power resource 310 to provide adequate power to components of the data center 300. When expressed as a constraint, IHS-level power consumption may be a not-to-exceed value for a target average.

Other constraint may include a workload profile, such as the type of tasks an IHS may handle. Examples of tasks may include computational, memory-intensive tasks, artificial intelligence (AI) training and/or prediction, and/or storage. Different workloads may have different requirements for power usage and different characteristics for thermal output. For instance, AI training workloads may use high graphics processor unit (GPU) performance and large memory, while storage workloads may require high input-output throughput and large disk capacity. Yet another constraint may include a number of IHSs in a rack. A number of IHSs may be expressed as a maximum number to be installed within a single rack (e.g., racks 301). This number may depend on the size of the IHSs in rack units U and the height of the rack. For example, a standard 42 U rack may hold up to 42 1U IHSs or 21 2U IHSs.

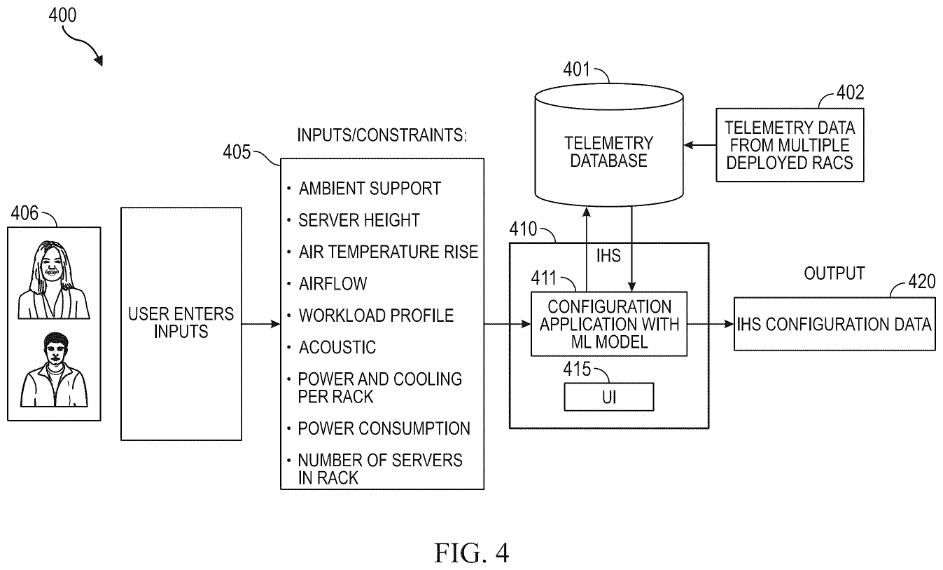

FIG. 4 is an illustration of example system 400, for configuring an IHS, according to some embodiments. For instance, system 400 may be used by a user to generate a hardware configuration of an IHS for deployment in a data center, such as data center 300 of FIG. 3. An example of an IHS, which may be the subject of the hardware configuration, is discussed above with respect to FIG. 2, and the IHS may be deployed within a chassis and a rack once it is manufactured.

System 400 includes telemetry database 401. In one example, telemetry database 401 may include a cloud-based database, which is configured to communicate with a multitude of deployed remote access controllers, where an example of a remote access controller includes remote access controller 255 of FIG. 2 and remote access controllers 100 of FIG. 1. For instance, there may be multiple deployed racks in multiple data centers around the world, and each of those racks may include IHSs, each of those IHSs including a respective remote access controller. Those remote access controllers may be configured to report telemetry data periodically to a cloud-based resource (not shown), which aggregates the telemetry data from the IHSs into telemetry data 402 and stores telemetry data 402 to telemetry database 401.

Telemetry data 402 may include a variety of reported operational data from deployed IHSs as well as configuration data from those deployed IHSs. Examples of telemetry data may include instantaneous power consumption of the IHS, instantaneous fan speed of the IHS, workload metrics of the IHS such as instantaneous input/output operations per second of the IHS, instantaneous exhaust temperature of the IHS, instantaneous ambient temperature of air coming into the IHS, instantaneous processor temperature, instantaneous network speed of the IHS, instantaneous memory use of the IHS as a percentage of maximum capability, instantaneous processor workload as a percentage of a maximum workload, and/or the like.

In addition to reporting telemetry data, a deployed remote access controller may also report configuration information. Examples of configuration information may include a quantity of central processing units (CPUs), CPU type, a quantity of graphics processing units (GPUs), GPU type, total available random-access memory (RAM), RAM type, quantity of fans or other cooling apparatus, fan type, chassis model type, rack model type, airflow capability, power capability, quantity and type of disk drives and network adapters, quantity and type of other IHSs in rack, quantity and type of power supply units, quantity and type of heatsinks, firmware versions, IHS model number, and/or the like.

A given, deployed remote access controller may report such telemetry and configuration data every minute, every hour, or other appropriate period. The cloud-based resource (not shown) may aggregate the periodic telemetry and configuration data into the telemetry data 402. Furthermore, the reported telemetry data from a deployed remote access controller may be included in a file or other data structure, which associates the configuration data with the telemetry data. As a result, the aggregated telemetry data 402 that is stored to database 401 may be comprehensive as to configuration and operational characteristics for different deployed systems over time.

The configuration application 411 may include a trained ML model. For instance, the ML model may be trained using the contents of the telemetry database 401. The trained ML model may be configured so that, during prediction phase, it may receive constraints as an input and then output a predicted hardware configuration of an IHS that conforms to the constraints.

An example of an ML model that may be used with configuration application 411 includes a Decision Tree Regressor (DTR) model, a XGBoost (XGB) model, or other appropriate model. A potential advantage of using a trained ML model with configuration application 411 is that a trained ML model may be able to predict a hardware configuration of an IHS, where that predicted hardware configuration is not represented in database 401 as having been previously deployed. In other words, the trained ML model may be configured to predict hardware configurations that differ from hardware configurations that are “known” by the database 401. Nevertheless, some embodiments may be configured to output both known and unknown configurations as appropriate.

System 400 may include an IHS 410, which may be the same as or similar to IHS 200 of FIG. 2. For instance, the IHS 410 may include one or more processors and memory, where the memory stores computer-readable instructions, which when executed by the one or more processors causes the IHS 410 to provide the functionality of configuration application 411. In this example, IHS 410 executes configuration application 411, which includes a pre-trained ML model. Either IHS 410 or another IHS (not shown) may be used during a training phase, as opposed to a prediction phase, of the ML model.

During use, a user (e.g. human user 406) may use user interface 415 to enter inputs, where those inputs specify one or more constraints of a desired IHS. For instance, the IHS may be expected to be deployed in a data center, where that data center has design features and mandates, which lead to some constraints. Examples of constraints are discussed above and are also illustrated in FIG. 4 as constraints 405. The input may include one or more of the constraints 405, and those constraints may be data center-level and may also include IHS-level constraints.

In one example use case, the user input may include constraints but may omit specifying any particular hardware component. Thus, in one example, a user may enter constraints including: air cooling only, quantity of IHSs in a rack being 20, AI workload profile, ambient temperature 25° C., temperature rise 30° C., IHS size 2U.

The trained ML model of the configuration application 411 may be configured to output IHS configuration data 420, where the configuration data 420 specifies a hardware implementation. The hardware implementation may include specifications at a component level of the IHS. For instance, the examples of configuration data discussed above that are stored in database 401 may be at a level of abstraction of the IHS configuration data 420. In other words, the configuration data 420 may specify, e.g., a quantity of central processing units (CPUs), CPU type, a quantity of graphics processing units (GPUs), GPU type, total available random-access memory (RAM), RAM type, quantity of fans or other cooling apparatus, fan type, chassis model type, rack model type, airflow capability, power capability, quantity and type of disk drives and network adapters, quantity and type of other IHSs in rack, quantity and type of power supply units, quantity and type of heatsinks, firmware versions, IHS model number, and/or the like.

The configuration application 411 may be configured to display the configuration data 420 on user interface 415. For instance, the user interface 415 may include a graphical user interface (GUI), which allows the user 406 to interact with the data, including making changes if appropriate. The user interface 415 may also provide an option for the user 406 to instruct an entity associated with the application 411 to manufacture and deliver the IHS according to the configuration data 420.

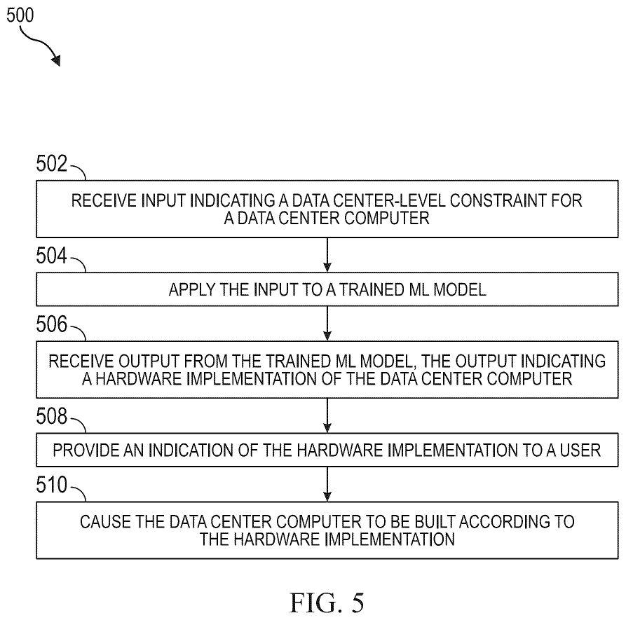

FIG. 5 is an illustration of example method 500, for configuring a data center computer, according to some embodiments. A data center computer may include a desired IHS for deployment in a data center, where that IHS may be the same as or similar to the IHS 200 described above with respect to FIG. 2. In one example, method 500 may be performed by an IHS, such as IHS 410 as it provides the functionality of configuration application 411 of FIG. 4.

Method 500 may be used in a variety of operations to configure an IHS for data center deployment. In one use case, a user may employ the configuration application 411 to predict a hardware configuration for an initial deployment, such as by predicting a hardware configuration that is not known by database 401. In another example operation, the ML model may be trained to choose a best fit among multiple pre-defined hardware configurations. In another operation, there may be deployed IHSs that are experiencing performance drift, such as operation characteristics that have changed since deployment. Examples of performance drift may include operating at different temperatures and fan speeds, which may be due to different workloads, hardware or firmware updates, and/or the like. Performance drift may cause a deployed system to operate outside of constraints. The configuration application 411 may be configured to detect performance drift and to predict a hardware configuration for the IHS to bring the IHS back to original specifications and constraints. For instance, the ML model may have been trained to receive the constraints (e.g., inputs 405) as well as a current configuration for hardware. The ML model may be further trained to output proposed changes to the deployed system to bring the deployed system back to a desired configuration to conform to the constraints.

Action 502 includes receiving input indicating a data center-level constraint for a data center computer. In this example, a data center computer may be a proposed IHS, conforming to an architecture, an example of which is described above with respect to FIG. 2. In an example operation for an initial configuration, the data center computer has not yet been manufactured, though in an operation directed at a deployed system, the data center computer may be already manufactured and deployed.

Action 502 may include receiving the user input at a user interface, such as user interface 415 of FIG. 4. Furthermore, examples of data center-level constraints are discussed above, such as ambient support, air temperature rise, airflow, and the like.

In some examples, the input may include no data to indicate a particular hardware configuration. For instance, in examples for an initial configuration, the input may be indicative of constraints, though no particular model or hardware configuration (other than number of IHSs in a rack and a size of the IHS in U units) may be indicated. However, in an operation directed at a deployed system, the input may include at least some hardware implementation data of the deployed system.

Action 504 includes applying the input to a trained ML model. An example of a trained ML model is discussed above with respect to application 411 of FIG. 4. Action 504 may include operating the trained ML model in a prediction phase.

Action 506 may include receiving output from the trained ML model. Furthermore, the output may indicate a hardware implementation of the data center computer. An example of the output is described above with respect to the configuration data 420 of FIG. 4.

Furthermore, method 500 is not limited to configuring a single IHS. Rather, the output may indicate a quantity of IHSs to a rack, a number of racks for a data center, and/or the like. Furthermore, the output may indicate either multiple instances of a same type of IHS in a given rack or may indicate different types of IHSs within a given rack.

Action 508 includes providing an indication of the hardware implementation to the user. As noted above, the user may employ a user interface of an IHS (e.g., IHS 410), and the output may be provided to the user on that interface or a different interface. The interface may allow the user to browse the hardware implementation, change or edit one or more items of the hardware implementation, and choose to initiate the manufacture and deployment of the data center computer.

Action 510 includes causing the data center computer to be built according to the hardware implementation. For instance, the user may select an option to instruct the data center computer to be built, such as to be manufactured, implemented within a rack, and the rack to be deployed in a data center. In one example, the configuration application 411 may be associated with a party that builds and deploys IHSs for data centers. The configuration application 411 may take user instructions to build and deploy the data center computer, deliver those instructions to the party, which causes the party to build and deploy the data center computer according to the user instructions and the hardware implementation data.

The scope of implementations is not limited to the series of actions shown in FIG. 5. Rather, other embodiments may add, omit, rearrange, or modify one or more of the actions. For instance, one example may include a user starting over with a different set of constraints without causing the data center computer to be built. For instance, the user may employ multiple cycles of actions 502-508 to discover a desired hardware implementation that may satisfy one or multiple constraints. Furthermore, the user may cause multiple different hardware implementations to be built, using method 500.

It should be understood that various operations described herein may be implemented in software executed by logic or processing circuitry, hardware, or a combination thereof. The order in which each operation of a given method is performed may be changed, and various operations may be added, reordered, combined, omitted, modified, etc. It is intended that the invention(s) described herein embrace all such modifications and changes and, accordingly, the above description should be regarded in an illustrative rather than a restrictive sense.

Although the invention(s) is/are described herein with reference to specific embodiments, various modifications and changes can be made without departing from the scope of the present invention(s), as set forth in the claims below. Accordingly, the specification and figures are to be regarded in an illustrative rather than a restrictive sense, and all such modifications are intended to be included within the scope of the present invention(s). Any benefits, advantages, or solutions to problems that are described herein with regard to specific embodiments are not intended to be construed as a critical, required, or essential feature or element of any or all the claims.

Unless stated otherwise, terms such as “first” and “second” are used to arbitrarily distinguish between the elements such terms describe. Thus, these terms are not necessarily intended to indicate temporal or other prioritization of such elements. The terms “coupled” or “operably coupled” are defined as connected, although not necessarily directly, and not necessarily mechanically. The terms “a” and “an” are defined as one or more unless stated otherwise. The terms “comprise” (and any form of comprise, such as “comprises” and “comprising”), “have” (and any form of have, such as “has” and “having”), “include” (and any form of include, such as “includes” and “including”) and “contain” (and any form of contain, such as “contains” and “containing”) are open-ended linking verbs. As a result, a system, device, or apparatus that “comprises,” “has,” “includes” or “contains” one or more elements possesses those one or more elements but is not limited to possessing only those one or more elements. Similarly, a method or process that “comprises,” “has,” “includes” or “contains” one or more operations possesses those one or more operations but is not limited to possessing only those one or more operations.

1. An IHS (Information Handling System) comprising:
a plurality of managed hardware components;
one or more processors; and
one or more memory devices coupled to the one or more processors, the memory devices storing computer-readable instructions that, upon execution by the one or more processors, cause the IHS to:
receive input indicating a data center-level constraint for a data center computer;
apply the input to a trained machine learning (ML) model to cause the ML model to generate configuration data for the data center computer, wherein the configuration data specifies a hardware implementation of the data center computer having characteristics conforming to the data center-level constraint; and
provide the configuration data for the data center computer to a user via a user interface.

2. The IHS of claim 1, wherein the data center-level constraint comprises an ambient temperature of the data center.

3. The IHS of claim 1, wherein the data center-level constraint comprises an air temperature rise of exhaust from the data center computer to the data center.

4. The IHS of claim 1, wherein the data center-level constraint comprises a volume of air flow between the data center computer and the data center.

5. The IHS of claim 1, wherein the data center-level constraint comprises a noise level produced by the data center computer within the data center.

6. The IHS of claim 1, wherein the data center-level constraint comprises an amount of power consumed by a rack, configured to host the data center computer, and received from a data center-level shared power resource.

7. The IHS of claim 1, wherein the data center-level constraint comprises an amount of cooling consumed by a rack, configured to host the data center computer, and received from a data center-level shared cooling resource.

8. The IHS of claim 1, wherein the configuration data comprises an identification of a model number of the data center computer and a number of instances of the data center computer to a rack.

9. The IHS of claim 1, wherein the configuration data includes an identification of cooling system hardware for the data center computer.

10. The IHS of claim 1, wherein the input further indicates a workload profile of the data center computer.

11. The IHS of claim 1, wherein the input does not include an identification of a model number of the data center computer.

12. A method comprising:
receiving input indicating an information handling system (IHS) size and a data center-level thermal constraint;
applying the input to a trained machine learning (ML) model to cause the ML model to generate configuration data for an IHS, wherein the configuration data specifies a hardware implementation of the data center computer having characteristics conforming to the IHS size and the data center-level thermal constraint; and
providing the configuration data for the data center computer to a user via a user interface.

13. The method of claim 12, wherein the data center-level thermal constraint comprises an ambient support temperature of the data center.

14. The method of claim 12, wherein the IHS size indicates a size in rack units (U).

15. The method of claim 12, wherein applying the input to the trained ML model includes causing the ML model to operate in a prediction phase.

16. The method of claim 12, wherein the data center-level thermal constraint comprises air temperature rise.

17. The method of claim 12, further comprising:
causing the IHS to be built according to the hardware implementation.

18. A computer-readable storage device having instructions stored thereon for configuring a data center computer, wherein execution of the instructions by one or more processors of an information handling system (IHS) causes the one or more processors to:
receiving input indicating a data center mandate for a thermal characteristic of the data center computer and a power characteristic of the data center computer;
applying the input to a trained ML model to cause the trained ML model to generate a predicted hardware configuration for the data center computer, wherein the hardware configuration comprises a component-level specification for the data center computer; and
outputting the predicted hardware configuration to a user with an option to cause the data center computer to be built according to the hardware configuration.

19. The computer-readable storage device of claim 18, wherein the thermal characteristic comprises an air temperature rise value.

20. The computer-readable storage device of claim 18, wherein the power characteristic comprises a power use per rack value.
